(19) United States
(12) Patent Application Publication
(10) Pub. No.: US 2025/0102631 A1
(43) Pub. Date: Mar. 27, 2025

(54) Electronic Devices with Transmitter-Receiver Array

(71) Applicant: Apple Inc., Cupertino, CA (US)

(72) Inventors: Siddharth Joshi, Saint-Egreve (FR); Arnaud Laflaquiere, Paris (FR); Nicolas Hotellier, Champagnier (FR); Cristiano L. Niclass, San Jose, CA (US); Keith Lyon, San Jose, CA (US)

(21) Appl. No.: 18/673,072

(22) Filed: May 23, 2024

Related U.S. Application Data
(60) Provisional application No. 63/540,851, filed on Sep. 27, 2023.

(51) Int. Cl. G01S 7/481; H01S 5/02; H01S 5/14; H01S 5/183; H01S 5/42

(52) U.S. Cl. CPC G01S 7/4813; H01S 5/0206; H01S 5/14; H01S 5/18305; H01S 5/18361; H01S 5/423

(57) ABSTRACT

Disclosed are electronic devices that include an array of light emitting diodes and photosensors formed in a single semiconductor chip. The light emitting diodes may be structured as vertical exterior cavity surface-emitting laser diodes (VECSELs). The photosensors may be formed as resonant cavity photosensors (RCPDs). The VECSELs and the RCPDs of the array may be formed in a common set of semiconductor layers of the single semiconductor chip and separated by isolation regions formed in the common set of semiconductor layers. Also disclosed are dual chip transmitter-receiver systems including a first semiconductor chip having an array of both VECSELs and RCPDs formed in common set of semiconductor layers, and a second semiconductor chip electrically connected to the first semiconductor chip and including control circuitry to enable laser emission from the VECSELs and light reception by the RCPDs.

### CROSS-REFERENCE TO RELATED APPLICATION

This application is a nonprovisional and claims the benefit under 35 U.S.C. § 1.119 (e) of U.S. Provisional Patent Application No. 63/540,851, filed Sep. 27, 2023, the contents of which are incorporated herein by reference as if fully disclosed herein.

### FIELD

The present disclosure generally relates to electronic devices having a light transmitter-receiver array. The light transmitter-receiver array includes both light transmitters and light receivers.

The light transmitters may be implemented as laser diodes, such as vertical exterior cavity surface-emitting laser diodes (VECSELs). The light receivers may be implemented as photosensors, such as resonant-cavity photosensors (RCPDs).

### BACKGROUND

Electronic devices with components or systems for sensing environments of electronic devices are commonplace in today's society. Examples of such electronic devices include cell phones, tablet computers with cameras, light detection and ranging (LIDAR) systems, camera-based sensors on automobiles, security systems, and the like. Some of these electronic devices use an array of laser diodes, such as an array of vertical cavity surface-emitting laser diodes (VCSELs) or edge-emitting laser diodes (EEL). Laser light emitted from the array of laser diodes may be received at an array of photosensors, such as an array of photosensors, after reflecting or scattering from one or more objects in a field of view of the array of photosensors.

Such electronic devices may thus need to include two arrays, each having associated electronic circuitry.

### SUMMARY

This summary is provided to introduce a selection of concepts in a simplified form that are further described below in the Detailed Description section. This summary is not intended to identify key features or essential features of the claimed subject matter, nor is it intended to be used as an aid in determining the scope of the claimed subject matter.

Disclosed herein are electronic devices, including electronic light emitting and light sensing devices, operable to emit light into an environment, and to receive light that is reflected or scattered from the environment, to determine information regarding one or more objects in the environment.

More specifically, in a first family of embodiments, the present disclosure describes electronic devices that include a first semiconductor chip having an array of vertical external cavity surface-emitting laser diodes (VECSELs) and resonant cavity photosensors (RCPDs) formed in a common set of semiconductor layers on a substrate of the first semiconductor chip, and a second semiconductor chip joined to the first semiconductor chip. The second semiconductor chip includes electronic circuitry connected to the first semiconductor chip and operable to control the VECSELs and the RCPDs of the first semiconductor chip. The VECSELs emit laser light through the substrate. The common set of semiconductor layers is positioned between the substrate and the second semiconductor chip. The VECSELs and RCPDs alternate in position across each row of the array. The VECSELs and RCPDs are separated by isolation regions in the common set of semiconductor layers.

In some embodiments, the common set of semiconductor layers include an active layer, a first set of distributed Bragg reflector (DBR) layers disposed between the active layer and the substrate, and a second set of DBR layers disposed between the active layer and the second semiconductor chip. The first DBR layers may have n-type doping, with the second DBR layers having p-type doping. The semiconductor of the first semiconductor chip may be gallium Arsenide (GaAs). The semiconductor of the second semiconductor chip may be silicon (Si).

In a second family of embodiments, the present disclosure describes electronic devices that include a GaAs chip having an array of backside illuminated (BSI) laser diodes and RCPDs formed in a common set of semiconductor layers on a substrate of the GaAs chip, and a silicon chip that includes electronic circuitry connected to the GaAs chip. The electronic circuitry is operable to control the light emission of BSI laser diodes through the substrate and light reception by the RCPDs. The common set of semiconductor layers is positioned between the substrate and the silicon chip.

In some embodiments, the common set of semiconductor layers may include an active layer, a first set of DBR layers disposed between the active layer and the substrate of the GaAs chip, and a second set of DBR layers disposed between the active layer and the silicon chip. The first set of DBR layers may form a partial DBR mirror and the second set of DBR layers may form a full DBR mirror, and/or the first set of DBR layers may provide a lower reflectivity than the second set of DBRs. A light emission side of the substrate, opposite to the first set of DBR layers, may include a set of external cavity reflectors. The BSI laser diodes, in combination with the set of external cavity reflectors, may form a set of VECSELs.

In a third family of embodiments, the present disclosure describes electronic devices that include a first semiconductor chip including an array of diode structures formed in a common set of semiconductor layers on a substrate of the first semiconductor chip, and a second semiconductor chip electrically connected to the first semiconductor chip that includes electronic circuitry connected to the first semiconductor chip. The common set of semiconductor layers includes an active layer, a first set of DBR layers disposed between the active layer and the substrate, and a second set of DBR layers disposed between the active layer and the second semiconductor chip. The anodes of the diode structures include respective sections of the first set of DBR layers, and the cathodes of the diode structures include respective sections of the second set of DBR layers.

In some embodiments, the electronic circuitry of the second semiconductor chip may be operable to apply, in a first time interval, a forward bias to a set of the diode structures to cause the set of the diode structures to emit laser light through the substrate, and apply, in a second time interval, a reverse bias to the set of the diode structures so that the set of the diode structures function as resonant cavity photosensors. The first semiconductor chip may be a GaAs chip, the first set of DBR layers has n-type doping, and the second set of DBR layers has p-type doping.

### BRIEF DESCRIPTION OF THE DRAWINGS

The disclosure will be readily understood by the following detailed description in conjunction with the accompanying drawings, wherein like reference numerals designate like structural elements.

FIG. 1A illustrates a first view of a smart phone that may include a transmitter-receiver array, according to an embodiment.

FIG. 1B illustrates a second view of a smart phone that may include a transmitter-receiver array, according to an embodiment.

FIG. 1C is a block diagram of a LIDAR system that may include a transmitter-receiver array, according to an embodiment.

FIG. 2 is a block diagram of one row of a transmitter-receiver array and associated electrical components of a dual-chip transmitter-receiver system, according to an embodiment.

FIG. 3A is a plan view of a section of a transmitter-receiver array coupled to a control circuitry chip, according to an embodiment.

FIG. 3B is a top view of an embodiment of a configuration of electrical connections on a control circuitry subsystem chip, according to an embodiment.

FIG. 4A is a cross-section view of the transmitter-receiver array of FIG. 3A along the cut line A-A′, according to an embodiment.

FIG. 4B is a cross-section view of part of the transmitter-receiver array of FIG. 4A, according to an embodiment.

FIG. 5 is a circuit diagram of a first configuration of control circuitry components associated with the transmitter-receiver array of FIG. 3A, according to an embodiment.

FIG. 6 illustrates a circuit diagram of a second configuration of control circuitry components associated with the transmitter-receiver array of FIG. 3A, according to an embodiment.

FIG. 7 shows a circuit diagram of triggering and amplifying circuit components, such as may be part of the first or second configurations of the control circuitry associated with the transmitter-receiver array of FIG. 3A, according to an embodiment.

FIG. 8 is a sample electrical block diagram of an electronic device that includes an image sensor, according to an embodiment.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The embodiments described herein are directed to electronic devices that include at least a combined transmitter-receiver array. The combined transmitter-receiver array may contain both light transmitters, such as laser diodes, and photosensors, such as resonant cavity photosensors (RCPDs). The combined transmitter-receiver array may be formed on a single semiconductor chip.

The laser diodes of the combined transmitter-receiver array may be implemented as VECSELs. When formed in a semiconductor chip, a VECSEL is structured with one mirror, such as a distributed Bragg reflector (DBR), at one end of a lasing cavity and another mirror exterior to its diode structure. Under forward bias, an active region within the VECSEL emits a laser light through a light emission side of the combined transmitter-receiver array.

The photosensors of the combined transmitter-receiver array may be implemented with the structure of an RCPD. An RCPD includes a full or partial semiconductor mirror structure, such as a DBR, on each side of an active region or layer. Different doping types (n-type and p-type) of the two DBRs provide a diode structure. Under reverse bias, light received into the RCPD may alter a measurable electrical property of the RCPD, such as a photocurrent or a diode junction voltage, enabling properties of the received light to be detected or determined.

A combined transmitter-receiver array may be formed within a common set of semiconductor layers of the single semiconductor chip, the layers themselves formed on a substrate of the chip. The common set of semiconductor layers may include the layers of alternating refractive indices that form a first DBR of a first doping type, the semiconductor layers for an active region that generates laser light, and the layers for a second DBR of a second doping type. The VECSEL and the RCPD regions of the combined transmitter-receiver array may then be separated within the array by etching or other techniques.

Also disclosed herein are dual chip transmitter-receiver systems that include a joined pair of semiconductor chips. The first semiconductor chip may include a combined transmitter receiver array of laser diodes and photosensors, such as VECSELs and RCPDs and the second semiconductor chip may include control circuitry, such as timing, triggering, and amplifying elements, to control operations of the laser diodes and the photosensors. The two semiconductor chips may be joined by metal vias. The second semiconductor chip may also contain layers of metal connections that provide connections to the laser diodes and photosensors.

Although specific electronic devices are shown in the figures and described below, the combined transmitter-receiver arrays and/or the control circuitry chips described herein may be used with various electronic devices including, but not limited to, LIDAR systems, computer monitors, traffic detectors on automobiles, room mapping devices, and so on. Although various electronic devices are mentioned, the combined transmitter-receiver arrays and dual chip transmitter-receiver systems of the present disclosure may also be used in conjunction with other products and combined with various materials.

Other examples and implementations are within the scope and spirit of the disclosure and appended claims. For example, features implementing functions may also be physically located at various positions, including being distributed such that portions of functions are implemented at different physical locations.

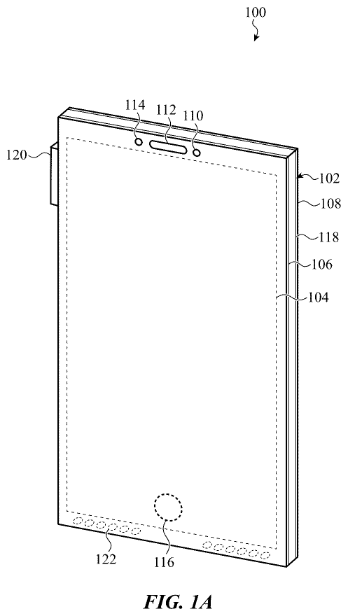

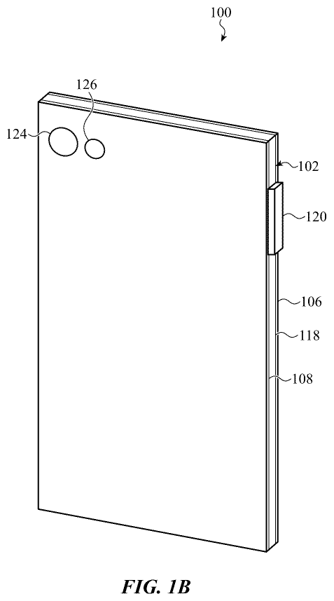

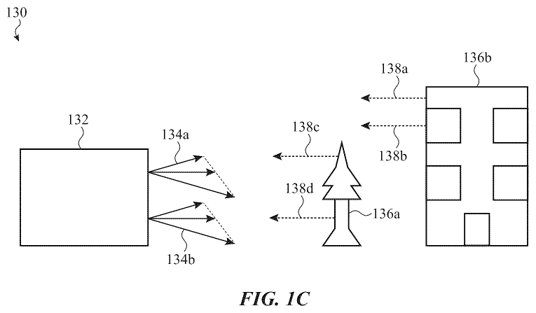

These and other embodiments are discussed below with reference to FIGS. 1A-8. However, those skilled in the art will readily appreciate that the detailed description given herein with respect to these figures is for explanatory purposes only and should not be construed as limiting.

Directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration and is not always limiting. The directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

FIGS. 1A and 1B show an example of an electronic device 100 that may include a dual-chip transmitter-receiver system or a combined transmitter-receiver array, as disclosed herein. The device's dimensions and form factor, including the ratio of the length of its long sides to the length of its short sides, suggest that the device 100 is a mobile phone (e.g., a smartphone). However, the device's dimensions and form factor are arbitrarily chosen, and the device 100 could alternatively be any portable electronic device including, for example a mobile phone, tablet computer, portable computer, portable music player, wearable device (e.g., an electronic watch, health monitoring device, or fitness tracking device), augmented reality (AR) device, virtual reality (VR) device, mixed reality (MR) device, gaming device, portable terminal, digital single-lens reflex (DSLR) camera, video camera, vehicle navigation system, robot navigation system, or other portable or mobile device. The device 100 could also be a device that is semi-permanently located (or installed) at a single location. FIG. 1A shows a front isometric view of the device 100, and FIG. 1B shows a rear isometric view of the device 100. The device 100 may include a housing 102 that at least partially surrounds a display 104. The housing 102 may include or support a front cover 106 or a rear cover 108. The front cover 106 may be positioned over the display 104 and may provide a window through which the display 104 may be viewed. In some embodiments, the display 104 may be attached to (or abut) the housing 102 and/or the front cover 106. In alternative embodiments of the device 100, the display 104 may not be included and/or the housing 102 may have an alternative configuration.

The display 104 may include one or more light-emitting elements, and in some cases may be a light-emitting diode (LED) display, an organic LED (OLED) display, a liquid crystal display (LCD), an electroluminescent (EL) display, or another type of display. In some embodiments, the display 104 may include, or be associated with, one or more touch and/or force sensors that are configured to detect a touch and/or a force applied to a surface of the front cover 106. The display 104 may additionally or alternatively include a dual-chip transmitter-receiver system or a combined transmitter-receiver array that is operable to perform, for example, gaze tracking of a user.

The various components of the housing 102 may be formed from the same or different materials. For example, a sidewall 118 of the housing 102 may be formed using one or more metals (e.g., stainless steel), polymers (e.g., plastics), ceramics, or composites (e.g., carbon fiber). In some cases, the sidewall 118 may be a multi-segment sidewall including a set of antennas. The antennas may form structural components of the sidewall 118. The antennas may be structurally coupled (to one another or to other components) and electrically isolated (from each other or from other components) by one or more non-conductive segments of the sidewall 118. The front cover 106 may be formed, for example, using one or more of glass, a crystal (e.g., sapphire), or a transparent polymer (e.g., plastic) that enables a user to view the display 104 through the front cover 106. In some cases, a portion of the front cover 106 (e.g., a perimeter portion of the front cover 106) may be coated with an opaque ink to obscure components included within the housing 102. The rear cover 108 may be formed using the same material(s) that are used to form the sidewall 118 or the front cover 106. In some cases, the rear cover 108 may be part of a monolithic element that also forms the sidewall 118 (or in cases where the sidewall 118 is a multi-segment sidewall, those portions of the sidewall 118 that are conductive or non-conductive). In still other embodiments, all of the exterior components of the housing 102 may be formed from a transparent material, and components within the device 100 may or may not be obscured by an opaque ink or opaque structure within the housing 102.

The front cover 106 may be mounted to the sidewall 118 to cover an opening defined by the sidewall 118 (i.e., an opening into an interior volume in which various electronic components of the device 100, including the display 104, may be positioned). The front cover 106 may be mounted to the sidewall 118 using fasteners, adhesives, seals, gaskets, or other components.

A display stack or device stack (hereafter referred to as a “stack”) including the display 104 may be attached (or abutted) to an interior surface of the front cover 106 and extend into the interior volume of the device 100. In some cases, the stack may include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 106 (e.g., to a display surface of the device 100).

In some cases, a force sensor (or part of a force sensor system) may be positioned within the interior volume above, below, and/or to the side of the display 104 (and in some cases within the device stack). The force sensor (or force sensor system) may be triggered in response to the touch sensor detecting one or more touches on the front cover 106 (or a location or locations of one or more touches on the front cover 106), and may determine an amount of force associated with each touch, or an amount of force associated with a collection of touches as a whole. In some embodiments, the force sensor (or force sensor system) may be used to determine a location of a touch, or a location of a touch in combination with an amount of force of the touch. In these latter embodiments, the device 100 may not include a separate touch sensor.

As shown primarily in FIG. 1A, the device 100 may include various other components. For example, the front of the device 100 may include one or more front-facing cameras 110 (including one or more 3D image sensors or depth sensors), speakers 112, microphones, or other components 114 (e.g., audio, imaging, and/or sensing components) that are configured to transmit or receive signals to/from the device 100. In some cases, a front-facing camera 110, alone or in combination with other sensors, may be configured to operate as a bio-authentication or facial recognition sensor. In some embodiments, a flash or electromagnetic radiation source (e.g., a visible or IR light source) may be positioned near the front-facing camera. In some cases, the front-facing camera 110 may be positioned behind the display 104 and receive electromagnetic radiation (e.g., light) through the display 104. In some cases, a depth sensor may be used to determine a distance to a user or generate a depth map of the user's face, or determine a distance or proximity to an object or generate a depth map of the object or a field of view (FoV) that includes the object. The device 100 may also include various input devices, including a mechanical or virtual button 116, which may be accessible from the front surface (or display surface) of the device 100.

The device 100 may also include buttons or other input devices positioned along the sidewall 118 and/or on a rear surface of the device 100. For example, a volume button or multipurpose button 120 may be positioned along the sidewall 118, and in some cases may extend through an aperture in the sidewall 118. The sidewall 118 may include one or more ports 122 that allow air, but not liquids, to flow into and out of the device 100. In some embodiments, one or more sensors may be positioned in or near the port(s) 122. For example, an ambient pressure sensor, ambient temperature sensor, internal/external differential pressure sensor, gas sensor, particulate matter concentration sensor, or air quality sensor may be positioned in or near a port 122.

In some embodiments, the rear surface of the device 100 may include a rear-facing camera 124 that includes one or more 3D image sensors or depth sensors (see FIG. 1B) that may be implemented using a dual-chip transmitter-receiver system or a combined transmitter-receiver array. A flash or electromagnetic radiation source 126 (e.g., a visible or IR light source) may also be positioned on the rear of the device 100 (e.g., near the rear-facing camera). In some cases, the rear surface of the device 100 may include multiple rear-facing cameras.

FIG. 1C is a simplified block diagram 130 of a light detection and ranging system (LIDAR) 132, which may include one or more of the various embodiments disclosed herein. The LIDAR 132 may be used to detect distances to objects in an exterior environment, such as a tree 136a and a building 136b. The LIDAR 132 may use the detected distances to form a depth map or other image or images of the exterior environment. The LIDAR 132 may be handheld, mounted on a stand, or carried by a moving vehicle or airplane. In some embodiments, the LIDAR 132 may be user-facing (e.g., in the case of a LIDAR used as a facial recognition sensor).

The LIDAR 132 emits light directionally toward the objects. In the particular case shown in FIG. 1C, LIDAR 132 emits sequentially within a first plane multiple light pulses 134a, followed by sequentially emitting within a second plane a second set of light pulses 134b, and so on. Though just two planes are shown swept with the light pulses 134a and 134b, the LIDAR 132 may emit light pulses across more planes. The light pulses may be laser pulses, such as may be emitted from one or more laser diodes within the LIDAR 132. The plane of an emitted laser pulse and the direction within the plane is controlled by mechanisms within the LIDAR 132, such as steerable optics, or by sequential emission of the laser pulses from an array of laser diodes in which the laser diodes are aimed at different directions to allow sweeping, both vertically and horizontally, of the exterior environment.

The LIDAR 132 may receive reflections 138a-d of the emitted light pulses, such as by one or more photosensors, which may be disposed in an array. The photosensors may be implemented in one or more of various technologies and may be resonant cavity photosensors, single photon avalanche diodes, CMOS photosensors, or photosensors using another technology.

The LIDAR 132 may perform time-of-flight measurements between emissions of light pulses and receptions of reflections thereof, to estimate a distance to a part of an object along the direction of the emitted light pulse. Such directional distance estimates over the entirety of emitted light pulses may then be combined to detect objects, produce a depth map, or produce other types of information of the exterior environment of the LIDAR 132.

Alternatively, the laser diodes of the LIDAR 132 may be configured to undergo self-mixing interference (SMI) with reflections of their emitted light. In SMI, the reflections of the emitted laser light are received back into the resonant cavity of a laser diode, causing alteration of the emitted light, such as alteration of a frequency, with such an alteration in the light being a measurable parameter that may be measured by means of a bias current monitor or a photosensor (e.g., a photodiode) associated with the laser diode.

FIGS. 1A-C describe various examples of electronic devices that make use of emitted light and received reflections for sensing of an exterior environment and objects therein. However, one skilled in the art will recognize that other types and categories of electronic devices may also make use of emitted light and received reflections for sensing, and that the embodiments disclosed herein are not limited to any particular type or category of electronic device.

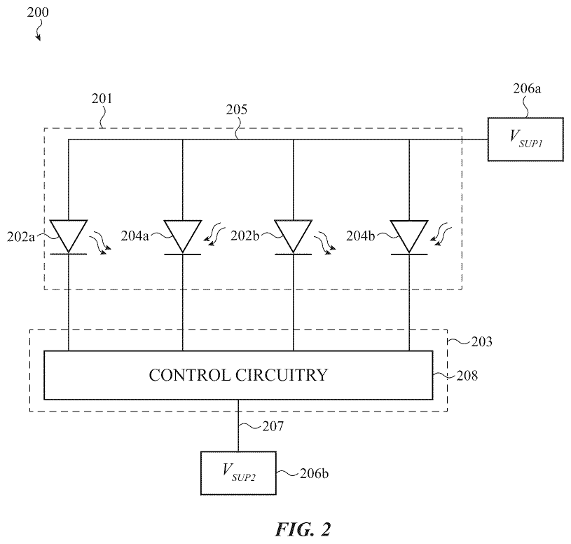

FIG. 2 is a block diagram of part of a dual chip transmitter-receiver system 200. The dual chip transmitter-receiver system 200 may be a part of an electronic device, such as an electronic light sensing device (ELSD), LIDAR system, camera, motion or object detection system, or a different electronic device that emits light into an environment and/or receives light from the environment, as described previously. Light received by an ELSD may include reflections of its own emitted light, and the received light may be used to determine aspects of objects in the electronic device's environment.

The dual chip transmitter-receiver system 200 may include a combined transmitter-receiver array 201 that includes both light transmitters, such as laser diodes, and photosensors, formed on a first semiconductor chip. The dual chip transmitter-receiver system 200 may also include a control circuitry subsystem 208 formed on a second semiconductor chip 203. The first semiconductor chip with the combined transmitter-receiver array 201 may be joined, such as in a stack configuration, to the second semiconductor chip 203 with metal interconnections, which may be through-chip vias. The dual chip transmitter-receiver system 200 may include further components, such as further control or processing units, which are not included on the second semiconductor chip 203.

The combined transmitter-receiver array 201 may include one or more rows containing VECSELs 202a and 202b, which alternate across the row with the photosensors 204a and 204b. Though only one row, with only two VECSELs 202a-b and two photosensors 204a-b, is shown in FIG. 2, one skilled in the art will recognize that the combined transmitter-receiver array 201 may have one or multiple rows, with each row having more or fewer VECSELs and photosensors. In some embodiments, the number of VECSELs and photosensors may be the same in each row and positioned as a rectangular array. In such embodiments, the VECSELs and photosensors may also alternate in each column, or alternatively each column may contain just VECSELs, or just photosensors. In alternative embodiments, the combined transmitter-receiver array 201 may include rows having different numbers of VECSELs and photosensors.

In various embodiments, and as described below, the photosensors 204a and 204b may be implemented as RCPDs having an active layer positioned between two DBRs.

The dual chip transmitter-receiver system 200 includes the control circuitry subsystem 208 that is connected at least to the combined transmitter-receiver array 201. The control circuitry subsystem 208 may include switching, enabling, amplifying, or other electrical components, which may function to trigger the VECSELs 202a-b to emit light, to trigger the photosensors 204a-b to receive light, to perform input/output operations related to signals related to received light, or other operations. The control circuitry subsystem 208 may connect to other elements of the dual chip transmitter-receiver system 200 not included on the second semiconductor chip 203, and to other of components (such as power supplies) of an electronic device that includes the dual chip transmitter-receiver system 200.

The dual chip transmitter-receiver system 200 may include, or be connected to, a first power supply 206a that is connected to the VECSELS 202a-b and the photosensors 204a-b of the combined transmitter-receiver array 201 by at least one connection 205. The connection 205 may be implemented as one or more metal traces on the semiconductor chip that includes the combined transmitter-receiver array 201. The first power supply 206a may be a separate component of an electronic device that includes the dual chip transmitter-receiver system 200.

The dual chip transmitter-receiver system 200 may include, or be connected to, a second power supply 206b that is connected through conductive link 207 to the control circuitry subsystem 208 on the second semiconductor chip 203. The control circuitry subsystem 208 may include metal vias from the second semiconductor chip 203 to connect to electrodes or contacts of the VECSELs or RCPDs in the combined transmitter-receiver array 201 in the first semiconductor chip.

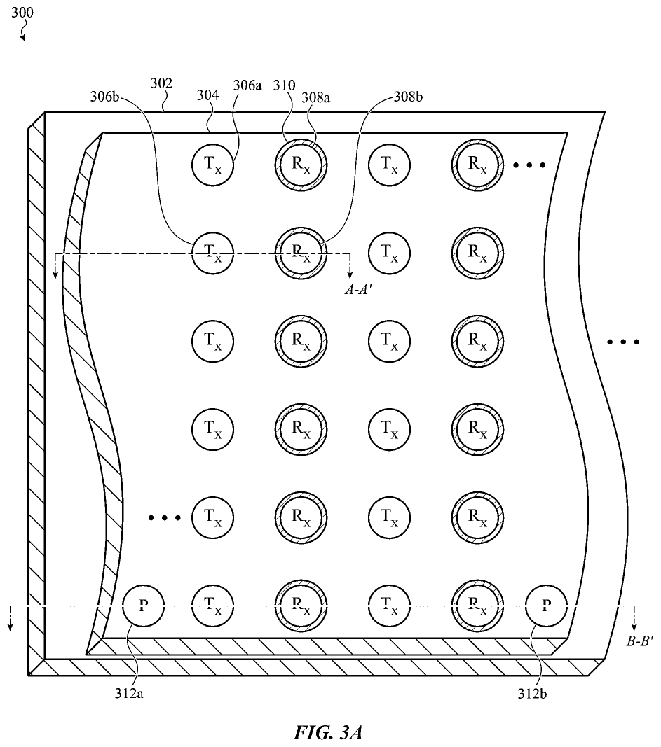

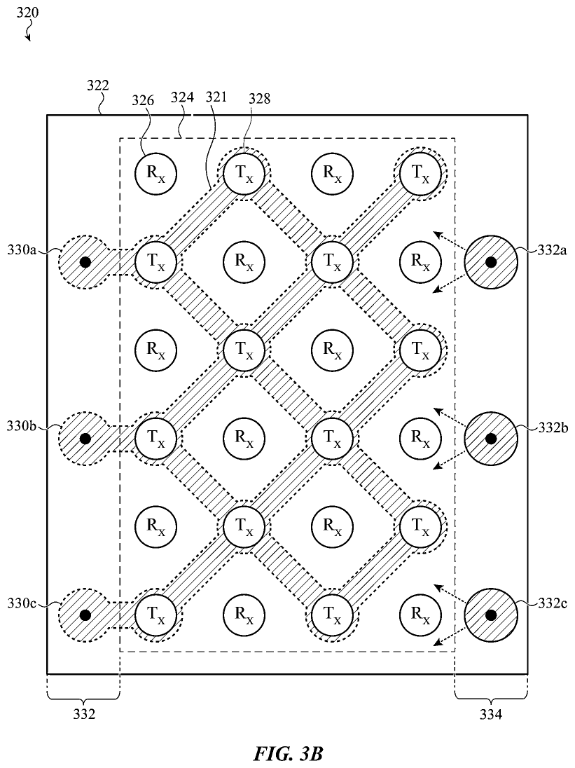

FIG. 3A is plan view of a section of a dual chip transmitter-receiver system 300. The dual chip transmitter-receiver system 300 includes a combined transmitter-receiver array 304 formed as part of a first semiconductor chip, which is electrically connected to a second semiconductor chip 302 that includes electronic circuitry. Some electronic circuitry of the second semiconductor chip 302 may control operations of the light transmitters and photosensors of the combined transmitter-receiver array 304. The second semiconductor chip 302 will also be referred to herein as the control circuitry chip 302.

The combined transmitter-receiver array 304 includes rows with respective alternating sequences of light transmitters (indicated by Tx), and photosensors (or “light receivers”, indicated by Rx). The first row (shown at the top of the combined transmitter-receiver array 304) includes the light transmitter 306a and the photosensor 308a, followed by a further alternating sequence of light transmitters and photosensors. The second row of the combined transmitter-receiver array 304 includes the light transmitter 306b and photosensor 308b, followed by a further alternating sequence of light transmitters and photosensors. In this embodiment of the combined transmitter-receiver array 304, the first (leftmost) column contains just light transmitters, with subsequent (from left to right as shown) columns alternating between columns of just photosensors and columns of just light transmitters. In other embodiments, the configuration of the combined transmitter-receiver array 304 may be such that within each column the light transmitters and photosensors also alternate. In still further embodiments, different arrangements of the light transmitters and photosensors may be used, for example, one light transmitter followed in each row by two photosensors, or other arrangements.

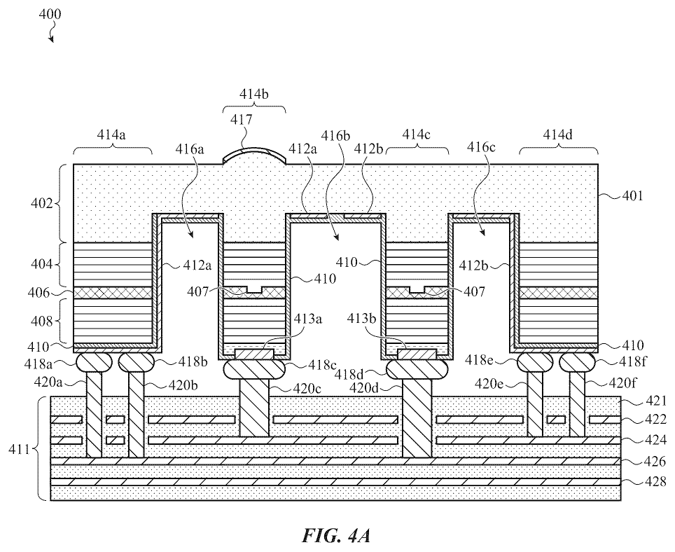

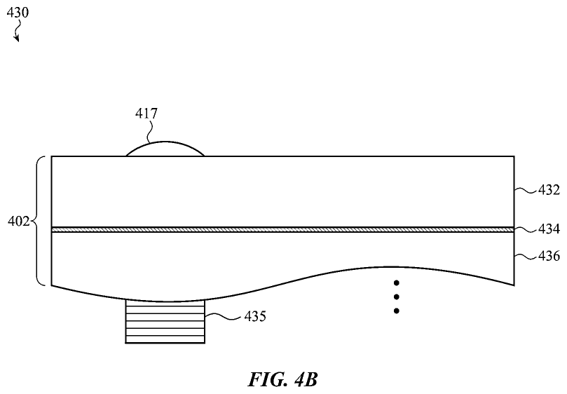

The photosensor 308a, as well as the other photosensors of the combined transmitter-receiver array 304, have a surrounding isolation region 310, that forms an insulating, electrical, or physical separation between the photosensor 308a and the surrounding semiconductor material of the first semiconductor chip in which the combined transmitter-receiver array 304 is formed. The isolation region 310 may be a trench etched into the first semiconductor chip, an etched trench in which an insulator (for example, silicon dioxide) has been deposited, a surrounding shell or layer of insulating material, or another separation technology. Further details are described below in relation to FIG. 4A.

The light transmitters 306a-b and the other light transmitters of the combined transmitter-receiver array 304 may be formed as backside illuminated (BSI) laser diodes. The combined transmitter-receiver array 304 may be formed with BSI laser diodes by deposition of various semiconductor layers on a substrate to form the laser cavity, which may be formed to include quantum wells, and the laser diodes end mirrors. The laser light is emitted through the substrate, which is the light emission side of the combined transmitter-receiver array 304.

In more specific embodiments of BSI technology, the light transmitters 306a-b and the other light transmitters of the combined transmitter-receiver array 304 may be VECSELs, and the photosensors 308a-b and the other photosensors may be RCPDs, both formed into a common set of layers formed, such as by deposition, on a substrate of the first semiconductor chip. Further details of these layers are described below in relation to FIG. 4A.

Some rows of the combined transmitter-receiver array 304 may include transmission and reception connection pillars, such as transmission connection pillar 312a and reception connection pillar 312b in the bottom row of the combined transmitter-receiver array 304. The transmission connection pillar 312a and the reception connection pillar 312b may provide respective interconnections from the control circuitry chip 302 to the VECSELs and RCPDs of the combined transmitter-receiver array 304. The interconnections may provide one or more supply voltages, such as from the first power supply 206a of the embodiment of FIG. 2.

The dual chip transmitter-receiver system 300 includes the control circuitry chip 302, which may include interconnections and/or electronic circuit elements that enable or disable operations of the VECSELs and RCPDs of the combined transmitter-receiver array 304. Such operations include, but are not limited to, triggering the VECSELs to emit light, enabling or disabling the RCPDs to receive light, buffering or amplifying photocurrent outputs of the RCPDs, or other operations.

FIG. 3B shows a configuration 320 of a first semiconductor chip 324 with a combined transmitter-receiver array connected or joined to a control circuitry chip 322. The control circuitry chip 322 includes a pattern of conductive interconnections 321 or contacts. The pattern of conductive interconnections 321 may be formed as a planar layer of conductive material within the control circuitry chip 322. The pattern of conductive interconnections 321 provides electrical connection from a respective electrode (either the anode or cathode) of each of the light transmitters 328 (indicated by Tx) to first voltage supply or signal connection pads 330a-c. The first voltage supply or signal connection pads 330a-c may positioned in a first column 332. The voltage or signal connection pads 330a-c may be formed in the control circuitry chip 322. The voltage or signal connection pads 330a-c may connect to metal connectors that extend from the control circuitry chip 322 to electrical contacts in the first semiconductor chip 324.

Though not shown for clarity, one skilled in the art will recognize that the control circuitry chip 322 may also include a similarly shaped auxiliary pattern of conductive interconnections, such as by shifting the pattern of conductive interconnections 321 vertically, that extends from second voltage supply or signal connection pads 332a-c and that underlies and connects to the photosensors 326 (indicated by Rx). The second voltage supply or signal connection pads 332a-c may positioned in a second column 334. The auxiliary pattern of conductive interconnections may be formed as a planar layer of conductive material within a different planar layer within the control circuitry chip 322 than the planar layer of the pattern of conductive interconnections 321.

FIG. 4A is a cross-sectional view of a dual chip transmitter-receiver system 400, which may be similar to the dual chip transmitter-receiver system 300 of FIG. 3A. The cross-sectional view of the dual chip transmitter-receiver system 400 shows a first semiconductor chip 401 joined to a second semiconductor chip 411 in a stack configuration. The first semiconductor chip 401 includes a combined transmitter-receiver array, which may be as described for the embodiments of the combined transmitter-receiver array 304 of FIG. 3A. The second semiconductor chip 411 includes electronic components and connections that allow control of the combined transmitter-receiver array on the first semiconductor chip 401, and so will also be referred to as the control circuitry chip 411. As will be explained, the cross-sectional view of the dual chip transmitter-receiver system 400 will show certain details both along the cut lines A-A′ and B-B′ of the dual chip transmitter-receiver system 300 of FIG. 3A.

The first semiconductor chip 401 includes a substrate 402, which may be semi-insulating. In some embodiments, the first semiconductor chip 401 is formed with gallium arsenide (GaAs) as the semiconductor material to which doping and deposition layers are applied, but other semiconductor materials may be used. The second semiconductor chip 411 may have silicon (Si) as the semiconductor material to which doping and deposition are applied. In a first family of embodiments, the substrate 402 has n-type doping. As explained below, in another family of embodiments the doping types now to be described for the first semiconductor chip 401 for the first family may be reversed.

The first semiconductor chip 401 may be formed to initially have a common set of semiconductor layers. The common set of semiconductor layers may be formed by epitaxial deposition, ion implantation, or other technologies, and initially may be formed to extend across the first semiconductor chip and/or the semiconductor wafer from which the first semiconductor chip is fabricated. Particular sections or regions of the first semiconductor chip (or semiconductor wafer) are then etched to form an array of separate diode structures. The separate diode structures may then function in the dual chip transmitter-receiver system 300 as either BSI laser diodes, which may be VECSELs, or as photosensors, which may be RCPDs.

More specifically, for the embodiment shown in FIG. 4A, the first semiconductor chip 401 is formed with a first subset of semiconductor layers 404, formed on an interior side of the substrate 402, opposite to the light emission side of the substrate 402. The first subset of semiconductor layers 404 includes multiple layers of semiconductor material with alternating indices of refraction that in the completed dual chip transmitter-receiver system 300 may form a first DBR for the BSI laser diodes, such as VECSELs. In the embodiment shown in FIG. 4A, the first DBR layers have n-type doping. In various embodiments, the number of layers in the first subset of semiconductor layers 404 may be sufficient to form either a full DBR, or a be a reduced number to form a partial DBR (such as may be the case of a VECSEL).

The first semiconductor chip 401 includes a second subset of one or more semiconductor layers forming an active region 406 in which either laser light may be generated if the diode structure is forward biased, or in which, under a reverse bias of the diode structure, a photocurrent or other measurable parameter may be induced when light is received. The active region 406 may be formed so that the resulting BSI laser diode is a quantum well laser, with either a single quantum well layer or multiple quantum well layers. The active region 406 may be formed with light emitting or receiving regions 407.

The first semiconductor chip 401 is formed with a third subset of semiconductor layers 408, formed on the layers of active region 406, opposite from the first subset of semiconductor layers 404. The second subset of semiconductor layers 408 includes multiple layers of semiconductor material with alternating indices of refraction that in the completed dual chip transmitter-receiver system 300 may form a second DBR for the BSI laser diodes, such as VECSELs. In the embodiment shown in FIG. 4A, the second DBR layers have p-type doping. In various embodiments, the number of layers in the third subset of semiconductor layers 408 may be sufficient to form a full DBR.

After the first, second, and third subsets of semiconductor layers, 404, 406, 408, have been formed on the substrate 402, void regions 416a-c may be excised or etched from the common set of semiconductor layers. The excising may thus produce pilar-shaped diode structures 414a-d (or mesas) extending from the substrate 402. For brevity of description, FIG. 4A shows only the four diode structures 414a-d. The cut line A-A′ shown in FIG. 3A corresponds to the cross section extending from the void region 416a to the void region 416c. One skilled in the art will recognize that additional pairs of diode structures etched into the common set of semiconductor layers may exist between the shown diode structures 414b and 414c. The cut line B-B′ of FIG. 3A corresponds to a cross section extending from the diode structure 414a to the diode structure 414d in which an additional pair of diode structures is present between the diode structures 414b and 414c.

The diode structures 414a-d may have formed on their surfaces an electrically insulating layer 410, such as silicon dioxide (SiO₂) or another material, to separate electrically the BSI laser diodes and the photosensors. The electrically insulating layer 410 may be formed by deposition technologies or other technologies. In some embodiments, an electrically insulating material may be filled into the void regions 416a-c.

In the embodiment of FIG. 4A, the diode structure 414b is further configured, as described below, to operate as a BSI laser diode. The diode structure 414c is further configured to operate as photosensor. The diode structures 414a and 414d are configured to support connections to the second semiconductor chip 411, and may not be configured either as a BSI laser or photosensor. The diode structures 414a and 414d may support electrical connections to voltage or signal connection pads in the second semiconductor chip 411, such as respectively one of the voltage or signal connection pads 330a-c or 332a-c described in relation to FIG. 3B.

The diode structure 414a has a first metal contact layer 412a extending from a surface facing the second semiconductor chip 411 to the top (at the interface with the substrate 402) of the first DBR layers of the diode structure 414b. The first metal contact layer 412a may form an annular ring shape at the top of the first DBR layers of the diode structure 414b. The first metal contact layer 412a may form a first electrode for the BSI laser diode. The diode structure 414b includes a first electrical contact 413a, which may be metal, formed at the base of the second DBR layers thereof. A forward bias to the BSI laser diode formed by the diode structure 414b occurs when a higher voltage is applied to the first electrical contact 413a than a voltage applied at the first metal contact layer 412a.

An external cavity reflector 417 may be disposed on a light emission side of the substrate 402. The external cavity reflector 417 may optionally be deposited on a lens, which may function to direct emitted laser light into an environment of the electronic device. In a first embodiment, the lens may be etched into the substrate 402. In a second embodiment, the lens may be a dielectric optical element that is attached to the substrate 402. In still other optional embodiments, different optical elements may be used instead of a lens, such as a diffraction grating or metasurface, depending on the application of the electronic device. The external cavity reflector 417 and lens combination is positioned so that, together with the diode structure 414b, a VECSEL structure is formed. Other external cavity reflectors may also be disposed on the substrate.

The diode structure 414d has a second metal contact layer 412b extending from a surface facing the second semiconductor chip 411 to the top of the first DBR layers of the diode structure 414c. The second metal contact layer 412b may form an annular ring shape at the top of the first DBR layers of the diode structure 414c. The second metal contact layer 412b may form a first electrode for a photosensor. The diode structure 414c includes a second electrical contact 413b formed at the base of the second DBR layers of the diode structure 414c. A reverse bias to the RCPD formed by the diode structure 414c occurs when a lower voltage is applied to the second electrical contact 413b than a voltage applied at the second metal contact layer 412b.

Though the substrate 402 and the first subset of semiconductor layers 404 were described as n-type, and the second subset of semiconductor layers 408 were described as p-type, in other embodiments of the first semiconductor chip 401, these doping types may be reversed, with corresponding changes in the applied voltages for emission and reception.

In the embodiment shown in FIG. 4A, the second semiconductor chip 411 includes multiple conductive layers embedded in a semiconductor substrate 421. The semiconductor substrate 421 may be silicon. Certain of the multiple conductive layers may be linked by conductive vias to contacts in the first semiconductor chip 401. The conductive layers may function as ground and/or shielding planes, or provide voltage or other signal connection, through the conductive vias, to the BSI laser diodes or RCPDs in the first semiconductor chip 401. The conductive layers and conductive vias may be a metal, such as gold, aluminum, or another metal or metal alloy.

The top conductive layer 422 may be disposed within the second semiconductor chip 411 toward the first semiconductor chip 401 and may serve as a shielding and/or grounding plane, and may serve to reduce electromagnetic interference between the first semiconductor chip 401 and the second semiconductor chip 411.

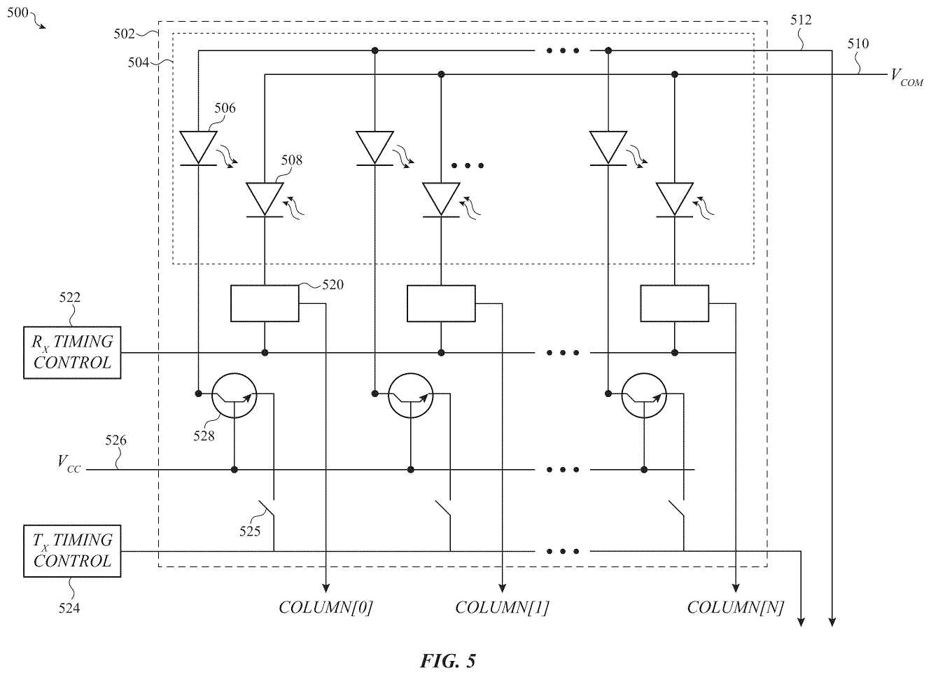

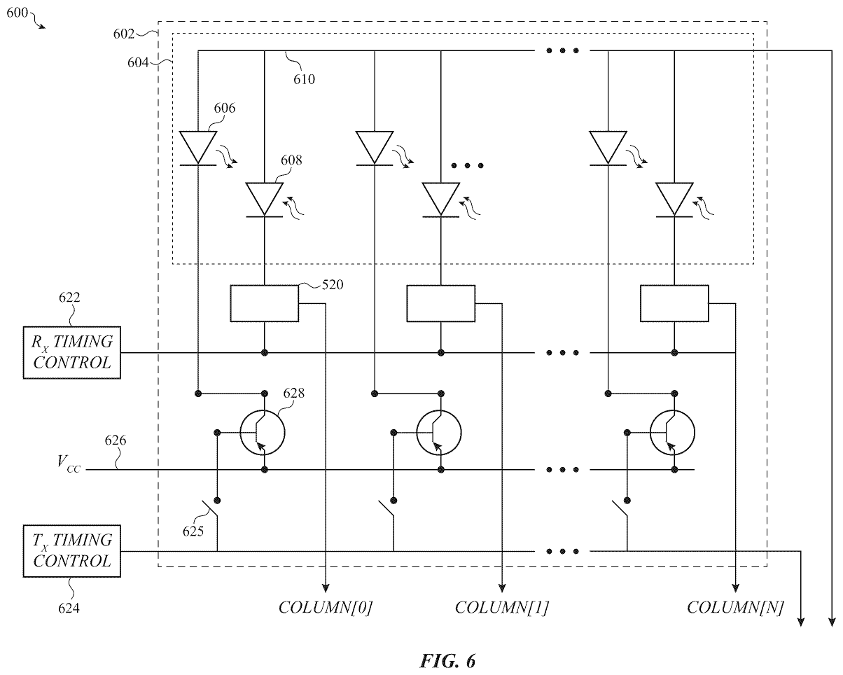

The conductive layer 424 may be used to apply a first voltage signal to the second (as enumerated from the left in FIG. 4A) conductive via 420c that extends through the semiconductor substrate 421 and any intervening conductive layers, to the second metal interconnect 418c, which connects to the first electrical contact 413a in the diode structure 414b. The conductive layer 424 also may be used to apply the first voltage signal to the fourth conductive vias 420e-f, which extend to the fourth metal interconnects 418e-f, which connect to the second metal contact layer 412b. Further timing and control circuitry in the second semiconductor chip 411, such as described in relation to FIGS. 5 and 6, may direct or control the application of the first voltage signal to a set of the VECSELs in the first semiconductor chip 401. In the embodiment shown in FIG. 4A, in which the third set of semiconductor layers 408 has p-type doping, the first voltage signal is applied to the anode of the diode structure 414b.

The conductive layer 426 may be used to apply a second voltage signal to the first (as enumerated from the left in FIG. 4A) conductive vias 420a-b that extend through the semiconductor substrate 421 and any intervening conductive layers, to the first metal interconnects 418a-b, which then connect to the first metal contact layer 412a of the diode structure 414a. The conductive layer 426 also may be used to apply the second voltage signal to the third conductive via 420d, which connects to the third metal interconnect 418d which connects to the second electrical contact 413b in the diode structure 414c. Further timing and control circuitry in the second semiconductor chip 411, such as described in relation to FIGS. 5 and 6, may direct or control the application of the second voltage signal to a set of the RCPDs in the first semiconductor chip 401. In the embodiment shown in FIG. 4A, in which the third set of semiconductor layers 408 has p-type doping, the second voltage signal is applied to the anode of the diode structure 414c.

In the embodiment shown in FIG. 4A, the metal interconnects 418a-b, 418c, 418d, and 418e-f may be implemented as gold, or other metal, contact balls. In additional and/or alternative embodiments, the metal interconnects may be implemented as electrically and mechanically connected metal pads respectively formed on the facing surfaces of the first semiconductor chip 401 and the second semiconductor chip 411.

The conductive layer 428 in the second semiconductor chip 411 may be a grounding layer, a shielding layer, a common ground plane, or may connect to control circuitry in the second semiconductor chip 411. The conductive layer 428 may have interconnections with the other conductive layers 424 and 426.

Though shown as a single conductive layer in FIG. 4A, in additional and/or alternative embodiments, the conductive layer 424 may have separated sections, so that different voltages or signals may be applied separately to the third conductive via 420c and to the fifth and sixth conductive vias 420e-f. In some cases, the conductive layer 424 may be further configured with separations to provide individual signal paths to the VECSELs of the combined transmitter-receiver array, such as to allow control circuitry to cause sequential light transmissions. Similar statements hold for the conductive layer 426, which may have internal separations to allow the control circuitry to cause sequential light receptions. Examples of control circuitry within the second semiconductor chip 411 to allow individual control of the BSI laser diodes and the RCPDs of the combined transmitter-receiver array of the first semiconductor chip 401 are presented in FIGS. 5 and 6.

The structure of the first semiconductor chip 401, in which the BSI laser diodes and the photosensors are both formed from the common set of semiconductor layers, may allow for dynamic conversion of their functions. For example, at a first time interval, a forward bias (a higher voltage is applied to the second electrical contact 413b than a voltage applied at the first metal contact layer 412a) may be applied to the diode structure 414b so that the diode structure 414b emits laser light. At a second time interval, a reverse bias may be applied to the diode structure 414b so that it may instead operate as an RCPD to detect received light.

FIG. 4B is a cross-sectional view 430 of further components that may be included in the substrate 402 of the dual chip transmitter-receiver system 400. The substrate 402 may have an external cavity reflector 417 disposed on a light emission side of the substrate. The external cavity reflector 417 is positioned on the substrate 402 directly opposite to the VECSEL 435, which may be as described for the diode structure 414b of FIG. 4A. The external cavity reflector 417 may operate as the reflector at the end of the exterior cavity of a VECSEL.

The substrate 402 may have internal layers, such as semiconductor layers with doping levels, or contact layers. In the embodiment of FIG. 4B, the substrate 402 may include at least one diode contact layer 434 that may connect to the anodes of the RCPDs of the array. The diode contact layer 434 may be metal layer deposited on the substrate 402 during fabrication. In this embodiment, as described and shown in relation to FIG. 4A, the diode contact layer 434 may be connected through the diode structure 414d to a signal or voltage source in the electronic circuitry on, or connected to, the control circuitry chip 411. Alternatively, the diode contact layer 434 may directly connect to electronic circuitry separate from the control circuitry chip 411.

In other embodiments, the diode contact layer 434 may instead connect to the anodes of the VECSELs of the array and through the Tx diode structure 414b to a signal or voltage source in the electronic circuitry on the control circuitry chip 411. In still other embodiments, there may be additional contact layers in the substrate 402.

The substrate 402 may include a doped layer 432 extending inward from the light emission side. The substrate 402 may include a non-intentionally doped (n.i.d) layer 436 between the diode contact layer 434 and the doped layers from which the VECSEL, such as VECSEL 435, and the RCPDs are formed. In the embodiment of FIG. 4A, in which the substrate 402 has n-type doping, the doped layer 432 has n-type doping, which may be a strong n-type doping concentration (in some cases above 10¹⁶ cm⁻³).

FIG. 5 shows a first circuit configuration 500 for certain electrical components in a control circuitry chip 502 of a dual chip transmitter-receiver system. The control circuitry chip 502 is electrically connected to the first semiconductor chip 504. The first semiconductor chip 504, which may be a GaAs chip, includes a combined transmitter-receiver array of light emitting diodes (such as BSI laser diodes and more specifically as VECSELs) and photosensors (such as RCPDs), as described previously. For simplicity of description, FIG. 5 shows only one row with BSI laser diodes alternating with RCPDs. The shown row contains N-many pairs of BSI laser diodes and RCPDs, with N-many signal detection output columns. Other rows of the of the combined transmitter-receiver array may connect to corresponding electrical components in the control circuitry chip 502. Also, electrical connections between the first semiconductor chip 504 and the control circuitry chip 502 are not shown for simplicity of description.

In the first circuit configuration 500, the cathodes of each of the light emitting diodes, such as light emitting diode 506, are connected to a collector of a respective transistor, such as transistor 528, which in the embodiment shown is an npn transistor, on the control circuitry chip 502. The base of the transistor 528 is connected to the voltage supply V_{CC} 526. A transmit timing signal source 524 can supply a trigger signal to the transmit control switch 525 to put a lower voltage at the emitter of the transistor 528 relative to the supply voltage on the supply line 512, and so cause the light emitting diode 506 to emit light. One skilled in the art will recognize that though the transistor 528 is shown as an npn transistor, other transistor types may be used, such as various FET or MOS technologies.

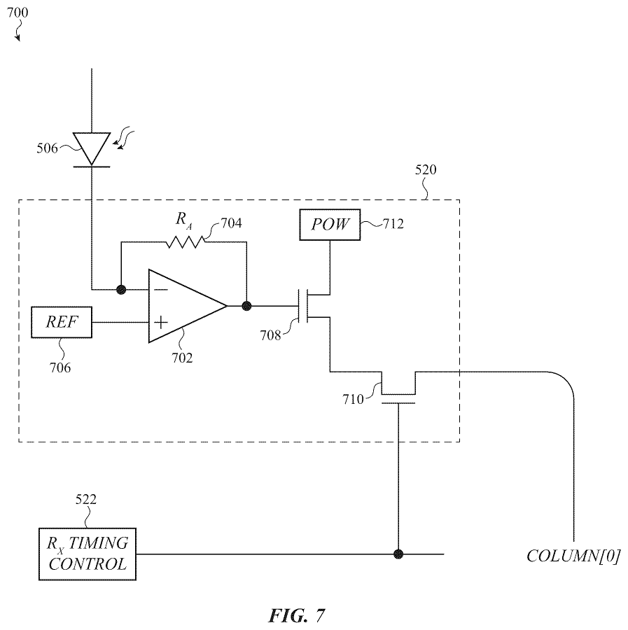

In the first circuit configuration 500, the cathode of each RCPD, such as RCPD 508, is connected to a buffering and/or amplifying circuit 520 (or just “buffering circuit 520”). An embodiment of the buffering circuit 520 is described in further detail in relation to FIG. 7. The buffering circuit 520 may provide a low resistance load to the RCPD 508 to amplify or buffer a current signal from the RCPD 508 during reception of light within the RCPD 508.

In addition to voltage supply and ground connections (not shown), the buffering circuit 520 is connected to a reception (Rx) control signal source 522. A reception signal from the Rx control signal source 522 may trigger light detection by the RCPD 508 by causing the buffering circuit 520 to apply a higher voltage to the cathode of the RCPD 508 than on the supply line 510 to reverse bias the RCPD 508.

FIG. 6 shows a second circuit configuration 600 for certain electrical components in a control circuitry chip 602 of a second semiconductor chip of a dual chip transmitter-receiver system. The control circuitry chip 602 is electrically connected to the first semiconductor chip 604. The first semiconductor chip 604, which may be a GaAs chip, includes a combined transmitter-receiver array of BSI laser diodes, which may be structured as VECSELs, and RCPDs, as described previously. For simplicity of description, FIG. 6 shows only one row with BSI laser diodes alternating with RCPDs. The shown row contains N-many pairs of laser diodes and RCPDs, with N-many signal detection output columns. Other rows of the of the combined transmitter-receiver array may connect to corresponding electrical components in the control circuitry chip 602. Also, transmission connection pillars and reception connection pillars of the combined transmitter-receiver array are not shown for simplicity of description.

In the second circuit configuration 600, the cathodes of each of the BSI laser diodes, such as BSI laser diode 606, are connected to collectors of respective transistors, such as transistor 628, which in the embodiment shown is pnp transistor, on the control circuitry chip 602. The emitter of the transistor 628 is connected the supply voltage V_{CC} 626, which is lower relative to the supply voltage on the supply line 610. A transmit timing signal source 624 can supply a trigger signal to the transmit control switch 625 to put a voltage at the base of the transistor 628, and so cause the BSI laser diode 606 to emit light. One skilled in the art will recognize that though the transistor 628 is shown as a pnp transistor, other transistor types may be used, such as various FET or MOS types.

In the second circuit configuration 600, the cathode of each RCPD, such as RCPD 608, is connected to a buffering and/or amplifying circuit 520 (or just “buffering circuit 520”), which may be as described above. The buffering circuit 520 may provide a low resistance load to the RCPD 608 to amplify or buffer a current signal from the RCPD 608 during reception of light within the RCPD 608.

In addition to voltage supply and ground connections (not shown), the buffering circuit 520 is connected to a reception (Rx) control signal source 622. The reception signal from the Rx control signal source 622 may trigger light detection by the RCPD 608 by causing the buffering circuit 520 to apply a higher voltage to the cathode of the RCPD 608 than on the supply line 610 to reverse bias the RCPD 608.

FIG. 7 is a circuit diagram of a circuit 700 for an embodiment of the buffering circuit 520 of the circuits shown in FIG. 5 and FIG. 6. The circuit 700 includes an amplifier 702, which may be a transimpedance amplifier. The amplifier 702 receives at its inverting input the output from the cathode of the light emitting diode 506, which may be a VECSEL or other BSI laser diode, and receives at its non-inverting input a reference 706, which may be a voltage source. The amplifier 702 has feedback through the feedback resistor 704 to the inverting input.

When the light emitting diode 506 does not receive light, no photocurrent is produced, and the cathode voltage of the light emitting diode 506 may be higher than the reference 706. In its inverting configuration, the amplifier 702 then produces a low voltage output at the base of the first output transistor 708, turning it off. When the light emitting diode 506 does receive light, it produces photocurrent, and the amplifier 702 may produce a high voltage output at the base of the first output transistor 708, allowing the first output transistor to conduct current from the voltage source 712. If, additionally, the Rx control signal source 522 provides a trigger voltage to turn on the second output transistor 710, a signal is produced on the output column. The signal may be a current or voltage signal and may be correlated with the light received at the light emitting diode 506. One skilled in the art will recognize that other related configurations of the circuit 700, such as a non-inverting configuration, may be implemented to apply amplification, buffering, or other signal operations on the output photocurrent of the light emitting diode 506.

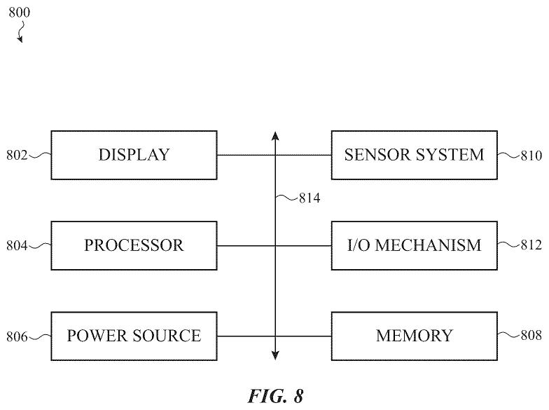

FIG. 8 shows a sample electrical block diagram of an electronic device 800 that include may be an electronic light sensing device or a combined transmitter-receiver array as described with reference to any of FIGS. 2-7. The electronic device 800 may take forms such as a hand-held or portable device (e.g., a smartphone, tablet computer, or electronic watch), a navigation system of a vehicle, and so on. The electronic device 800 may include an optional display 802 (e.g., a light-emitting display), a processor 804, a power source 806, a memory 808 or storage device, a sensor system 810, and an optional input/output (I/O) mechanism 812 (e.g., an input/output device and/or input/output port). The processor 804 may control some or all of the operations of the electronic device 800. The processor 804 may communicate, either directly or indirectly, with substantially all of the components of the electronic device 800. For example, a system bus or other communication mechanism 814 may provide communication between the processor 804, the power source 806, the memory 808, the sensor system 810, and/or the input/output mechanism 812.

The processor 804 may be implemented as any electronic device capable of processing, receiving, or transmitting data or instructions. For example, the processor 804 may be a microprocessor, a central processing unit (CPU), an application-specific integrated circuit (ASIC), a digital signal processor (DSP), a controller, or any combination of such devices. As described herein, the term “processor” is meant to encompass a single processor or processing unit, multiple processors, multiple processing units, or another suitably configured computing element or elements.

In some embodiments, the components of the electronic device 800 may be controlled by multiple processors. For example, select components of the electronic device 800 may be controlled by a first processor and other components of the electronic device 800 may be controlled by a second processor, where the first and second processors may or may not be in communication with each other.

The power source 806 may be implemented with any device capable of providing energy to the electronic device 800. For example, the power source 806 may include one or more disposable or rechargeable batteries. Additionally, or alternatively, the power source 806 may include a power connector or power cord that connects the electronic device 800 to another power source, such as a wall outlet.

The memory 808 may store electronic data that may be used by the electronic device 800. For example, the memory 808 may store electrical data or content such as, for example, audio and video files, documents and applications, device settings and user preferences, timing signals, control signals, data structures or databases, image data, maps, or focus settings. The memory 808 may be configured as any type of memory. By way of example only, the memory 808 may be implemented as random access memory, read-only memory, Flash memory, removable memory, other types of storage elements, or combinations of such devices.

The electronic device 800 may also include one or more sensors defining the sensor system 810. The sensors may be positioned substantially anywhere on the electronic device 800. The sensor(s) may be configured to sense substantially any type of characteristic, such as but not limited to, touch, force, pressure, electromagnetic radiation (e.g., light), heat, movement, relative motion, biometric data, distance, and so on. For example, the sensor system 810 may include a touch sensor, a force sensor, a heat sensor, a position sensor, a light or optical sensor, an accelerometer, a pressure sensor (e.g., a pressure transducer), a gyroscope, a magnetometer, a health monitoring sensor, an image sensor, a SPAD-based photon detector, and so on. Additionally, the one or more sensors may utilize any suitable sensing technology, including, but not limited to, capacitive, ultrasonic, resistive, optical, ultrasound, piezoelectric, and thermal sensing technology.

The I/O mechanism 812 may transmit and/or receive data from a user or another electronic device. An I/O device may include a display, a touch sensing input surface such as a track pad, one or more buttons (e.g., a graphical user interface “home” button, or one of the buttons described herein), one or more cameras (including one or more 2D or 3D image sensors (e.g., one or more SPAD-based photon detectors)), one or more microphones or speakers, one or more ports such as a microphone port, and/or a keyboard. Additionally, or alternatively, an I/O device or port may transmit electronic signals via a communications network, such as a wireless and/or wired network connection. Examples of wireless and wired network connections include, but are not limited to, cellular, Wi-Fi, Bluetooth, IR, and Ethernet connections. The I/O mechanism 812 may also provide feedback (e.g., a haptic output) to a user.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An electronic device, comprising:
a first semiconductor chip comprising an array of vertical external cavity surface-emitting laser diodes (VECSELs) and resonant cavity photosensors (RCPDs) formed in a common set of semiconductor layers on a substrate of the first semiconductor chip; and
a second semiconductor chip electrically connected to the first semiconductor chip, the second semiconductor chip comprising electronic circuitry connected to the first semiconductor chip and operable to control the VECSELs and the RCPDs;
wherein:
the VECSELs emit laser light through the substrate;
the common set of semiconductor layers is positioned between the substrate and the second semiconductor chip;
the VECSELs and RCPDs alternate in position across each row of the array; and
the VECSELs and RCPDs are separated by isolation regions in the common set of semiconductor layers.

2. The electronic device of claim 1, wherein the common set of semiconductor layers includes:
an active layer;
a first set of distributed Bragg reflector (DBR) layers disposed between the active layer and the substrate; and
a second set of DBR layers disposed between the active layer and the second semiconductor chip.

3. The electronic device of claim 2, wherein the substrate comprises gallium arsenide (GaAs).

4. The electronic device of claim 2, wherein:
the first set of DBR layers have n-type doping; and
the second set of DBR layers have p-type doping.

5. The electronic device of claim 2, wherein:
the first set of DBR layers have p-type doping; and
the second set of DBR layers have n-type doping.

6. The electronic device of claim 2, wherein the substrate further comprises:
an n-type doped layer proximate to a light emission side of the first semiconductor chip;
a diode contact layer containing at least one metal trace connected to the VECSELs and the RCPDs; and
a non-intentionally doped semiconductor layer.

7. The electronic device of claim 1, wherein the VECSELs comprise a set of external cavity reflectors positioned on a light emission side of the substrate.

8. The electronic device of claim 1, wherein the second semiconductor chip comprises a silicon (Si) substrate.

9. The electronic device of claim 8, wherein the second semiconductor chip comprises:
a first conductive layer;
a first set of conductive vias that connect the first conductive layer to anodes of a first set of the VECSELs of the first semiconductor chip;
a second conductive layer; and
a second set of metal vias that connect the second conductive layer to anodes of a first set of the RCPDs of the first semiconductor chip; and
a conductive layer configured as a grounding plane.

10. The electronic device of claim 9, wherein:
the first metal contact layer is configured to a receive a transmit signal to cause at least one VECSEL to transmit light; and
the second metal contact layer is configured to receive a reception signal to cause at least one RCPD to receive light.

11. The electronic device of claim 10, further comprising amplifying circuitry in the second semiconductor chip between cathodes of a first set of RCPDs and the second metal contact layer.

12. An electronic device, comprising:
a gallium arsenide (GaAs) chip comprising an array of adjacent backside illuminated (BSI) laser diodes and resonant cavity photosensors (RCPDs) formed in a common set of semiconductor layers on a substrate of the GaAs chip; and
a silicon chip comprising electronic circuitry connected to contacts on the GaAs chip and operable to control the BSI laser diodes and the RCPDs;
wherein:
the BSI laser diodes emit laser light through the substrate; and
the common set of semiconductor layers is positioned between the substrate and the silicon chip.

13. The electronic device of claim 12, wherein:
the common set of semiconductor layers comprises:
an active layer;
a first set of distributed Bragg reflector (DBR) layers disposed between the active layer and the substrate of the GaAs chip; and
a second set of DBR layers disposed between the active layer and the silicon chip.

14. The electronic device of claim 13, further comprising:
a set of external cavity reflectors disposed on a light emission side of the substrate, the light emission side of the substrate opposite to an interior side of the substrate on which the first set of DBR layers is formed; wherein,
the first set of DBR layers forms a partial DBR mirror;
the second set of DBR layers forms a full DBR mirror; and
the BSI laser diodes in combination with the set of external cavity reflectors form vertical external cavity surface-emitting laser diodes (VECSELs).

15. The electronic device of claim 14, wherein:
the first set of DBR layers has n-type doping; and
the second set of DBR layers has p-type doping.

16. The electronic device of claim 15, wherein the silicon chip comprises:
a first metal contact layer;
a first set of metal vias that connect from the first metal contact layer through the silicon chip to anodes of a first set of the VECSELs of the GaAs chip;
a second metal contact layer;
a second set of metal vias that connect from the second metal contact layer through the silicon chip to anodes of a first set of the RCPDs of the GaAs chip; and
a third metal contact layer configured as a common ground plane for at least one of the first set of the VECSELs and the first set of the RCPDs.

17. The electronic device of claim 16, wherein the electronic circuitry of the silicon chip comprises:
for each VECSEL, a respective transistor connected to a transmit control switch and to a respective cathode of the VECSEL; and
for each RCPD, a respective buffering circuit connected to a reception control signal source and to a respective cathode of the RCPD.

18. An electronic device comprising:
a first semiconductor chip comprising an array of diode structures formed in a common set of semiconductor layers on a substrate of the first semiconductor chip; and
a second semiconductor chip electrically connected to the first semiconductor chip, the second semiconductor chip comprising electronic circuitry connected to the first semiconductor chip;
wherein:
the common set of semiconductor layers includes:
an active layer;
a first set of distributed Bragg reflector (DBR) layers disposed between the active layer and the substrate; and
a second set of DBR layers disposed between the active layer and the second semiconductor chip;
anodes of the diode structures include respective sections of the first set of DBR layers;
cathodes of the diode structures include respective sections of the second set of DBR layers; and
the electronic circuitry of the second semiconductor chip is operable to:
apply, at a first time interval, a forward bias to at least one of the diode structures to cause the at least one diode structure to emit laser light through the substrate; and
apply, at a second time interval, a reverse bias to at least one of the diode structures so that the at least one diode structure functions as at least one resonant cavity photosensor (RCPD).

19. The electronic device of claim 18, further comprising:
the first semiconductor chip is a gallium arsenide (GaAs) chip;
the first set of DBR layers have n-type doping; and
the second set of DBR layers have p-type doping.

20. The electronic device of claim 18, further comprising:
a set of external cavity reflectors disposed on a light emission side of the substrate, the light emission side of the substrate opposite to an interior side of the substrate on which the first set of DBR layers is formed; and
the array of diode structures in combination with the set of external cavity reflectors form an array of vertical external cavity surface-emitting laser diodes during the first time interval.
